(19) United States
(12) Patent Application Publication
(10) Pub. No.: US 2026/0361236 A1
(43) Pub. Date: Nov. 12, 2026

(54) BIDIRECTIONAL MULTI-STAGE GALLIUM NITRIDE SWITCH AND POWER CONVERSION DEVICE COMPRISING SAME

(71) Applicant: HANWHA SOLUTIONS CORPORATION, Seoul (KR)

(72) Inventors: Jun Seong CHO, Seoul (KR); Youn Jong KANG, Seoul (KR); Kyung Su JUNG, Seoul (KR); Ki Woong BAE, Seoul (KR); Gi Yob PARK, Seoul (KR); Yeong Jin KIM, Seoul (KR); Su Chang LEE, Seoul (KR); Ju Hwan YUN, Seoul (KR)

(21) Appl. No.: 19/488,083

(22) PCT Filed: Dec. 5, 2024
(86) PCT No.: PCT/KR2024/019805

§ 371 Date: Nov. 26, 2025

(30) Foreign Application Priority Data
Dec. 5, 2024 (KR) 10-2023-0197049

(51) Int. Cl. H02M 7/5387; H10D 30/47; H10D 62/824; H10D 84/87

(52) U.S. Cl. CPC H02M 7/5387; H10D 30/475; H10D 84/87; H10D 62/824

(57) ABSTRACT

The disclosure relates to a bidirectional switch using a multistage gallium nitride switch and a power conversion device using the same. A bidirectional gallium nitride switch with a multistage structure according to the disclosure includes a structure in which source terminals of two gallium nitride switches are connected to each other and included within a single package and has an advantage of reducing volume and cost by controlling bidirectional current flow. In case of a common source terminal configuration, there is an advantage of simplifying the power circuit of a gate driver, and because there is no body diode, there is an effect of reducing switching loss.

### TECHNICAL FIELD

The disclosure relates to a power conversion device, and more particularly, to a power conversion device using a bidirectional gallium nitride switch as a switching element.

### BACKGROUND ART

A power conversion device is a device which converts electrical energy into various forms, such as converting direct current power or alternating current power into alternating current power or direct current power or converting voltage or frequency.

An inverter, one of the power conversion devices, is a device for converting direct current power into alternating current power and may include a converter unit and an inverter unit.

For example, the converter unit receives direct current power from an external power supply and converts the direct current power into pulsating current, and the inverter unit receives the pulsating current and converts the pulsating current into alternating current, which may then be transmitted to an external load or grid.

For example, the inverter may include various types of electrical devices. For example, to convert direct current power into alternating current power, silicon (Si)-based switches may switch at high speed to convert power, and the inverter may switch alternately according to a frequency value to convert direct current into alternating current with a sinusoidal waveform.

However, the silicon-based switches are not suitable for high-speed switching and may cause loss in low-power sections. Specifically, the silicon-based bidirectional switches may suffer loss due to breakdown voltages generated when body diodes of the switches themselves conduct. Accordingly, loss in the overall circuit may occur.

In some embodiments, two silicon-based switches may be required to configure a bidirectional switch. Therefore, the bidirectional switch configured by the two switches may also have the disadvantage of being bulky.

### DISCLOSURE OF INVENTION

### Technical Problem

The disclosure aims to provide a bidirectional gallium nitride switch capable of reducing switching loss by eliminating a body diode.

In some embodiments, the disclosure aims to provide a bidirectional switch capable of reducing package volume by including two switches in a single package.

In some embodiments, the disclosure aims to provide an inverter utilizing a bidirectional gallium nitride switch configured as a single package.

### Technical Solution

A bidirectional gallium nitride switch according to an aspect includes a first gallium nitride (GaN) switch and a second gallium nitride switch, each of which includes a gate terminal, a drain terminal, and a source terminal, and the drain terminal of the first gallium nitride switch and the drain terminal of the second gallium nitride switch are connected to each other, so that bidirectional current flow may be controlled by ON/OFF control of each of the gate terminal of the first gallium nitride switch and the gate terminal of the second gallium nitride switch.

The first gallium nitride switch and the second gallium nitride switch are included in the same package.

A power conversion device according to another aspect includes the bidirectional gallium nitride switch.

The power conversion device includes a primary-side full bridge circuit connected to an input power supply, a transformer for transmitting output of the full bridge circuit to a secondary side, and a converter unit for transmitting secondary-side output of the transformer to an output portion of the power conversion device.

The power conversion device may include an isolated inverter for converting primary-side direct current power into secondary-side alternating current power.

The converter unit may include a first bidirectional gallium nitride switch, a second bidirectional gallium nitride switch, a first capacitor, and a second capacitor.

The converter unit may include an end of secondary-side output of the transformer connected between the first bidirectional gallium nitride switch and the second bidirectional gallium nitride switch, which are connected in series to each other, and another end of secondary-side output of the transformer connected between the first capacitor and the second capacitor, which are connected in series to each other, and the first bidirectional gallium nitride switch and second bidirectional gallium nitride switch and the first capacitor and second capacitor are connected parallel to an output portion of the power conversion device.

The power conversion device includes a dual active bridge (DAB) structure in which a transformer and an inductor connected in series to the transformer are connected between a primary-side full bridge circuit and a secondary-side full bridge circuit, and the primary-side full bridge circuit may include a third bidirectional gallium nitride switch and a fourth bidirectional gallium nitride switch.

The primary-side full bridge circuit may include a first switching element and a second switching element connected in series to each other and a third bidirectional gallium nitride switch and a fourth bidirectional gallium nitride switch connected in series to each other, the elements and the switches connected in parallel to an input power supply.

The power conversion device includes a primary-side full bridge circuit, a first inductor, a second inductor, and a third capacitor connected to the primary-side full bridge circuit and connected in series to each other, a transformer including a primary-side connected in parallel to the first inductor or the second inductor, a fifth bidirectional gallium nitride switch connected in parallel to a secondary-side of the transformer, a fourth capacitor connected in parallel to the fifth bidirectional gallium nitride switch, and a secondary-side full bridge circuit connected in parallel to the fourth capacitor.

### Advantageous Effects of the Disclosure

A gallium nitride switch suitable for high-speed switching is used as a bidirectional switch. As a result, current flow with low switching loss can be implemented.

In some embodiments, by fabricating a bidirectional switch as a single die with a common drain terminal structure or a common source terminal structure and configuring the switch in a package, the volume of the entire switch may be reduced, and accordingly, the volume of a PCB may be minimized. Accordingly, manufacturing costs for a power conversion device may be reduced.

### BRIEF DESCRIPTION OF DRAWINGS

FIG. 1 is an exemplary diagram of a power supply structure of a building in which photovoltaic modules are installed according to an embodiment.

FIG. 2 is an exemplary diagram of a photovoltaic module including a power conversion device according to an embodiment.

FIGS. 3A to 4D are structural diagrams of bidirectional multistage gallium nitride switches according to an embodiment.

FIG. 5 is a circuit diagram of an inverter with a cycloconverter structure including a bidirectional multistage gallium nitride switch according to an embodiment.

FIG. 6 is a circuit diagram of an inverter with a DAB converter structure including a bidirectional multistage gallium nitride switch according to an embodiment.

FIG. 7 is a circuit diagram of an inverter with an LLC resonant converter structure including a bidirectional multistage gallium nitride switch according to an embodiment.

### BEST MODE FOR CARRYING OUT THE DISCLOSURE

A bidirectional gallium nitride switch according to an aspect includes a first gallium nitride (GaN) switch and a second gallium nitride switch, each of which includes a gate terminal, a drain terminal, and a source terminal, and the drain terminal of the first gallium nitride switch and the drain terminal of the second gallium nitride switch are connected to each other, so that bidirectional current flow may be controlled by ON/OFF control of each of the gate terminal of the first gallium nitride switch and the gate terminal of the second gallium nitride switch.

### Mode for Carrying Out the Disclosure

The objects, means and effects of the disclosure will become more apparent through the following detailed description with reference to the attached drawings, whereby a person having ordinary skill in the art to which the disclosure pertains will be able to easily implement the technical idea of the disclosure. In addition, when describing the disclosure, in case that it is determined that a detailed description of the prior art related to the disclosure may unnecessarily obscure the gist of the disclosure, the detailed description will be omitted.

In the specification, the terms “or,” “at least one,” or the like may refer to one of the words listed together or may refer to a combination of two or more words. For example, “or B” or “at least one of B” may include only one of A or B or may include both A and B.

In the specification, the terms such as “first,” “second,” or the like may be used to describe various components, but the components should not be limited by these terms. In addition, the terms should not be construed to limit the order of each component but may be used to distinguish a component from another component. For example, a “first component” may be named as a “second component,” and similarly, the “second component” may also be named as the “first component”.

Hereinafter, a preferred embodiment of the disclosure will be described in detail with reference to the attached drawings.

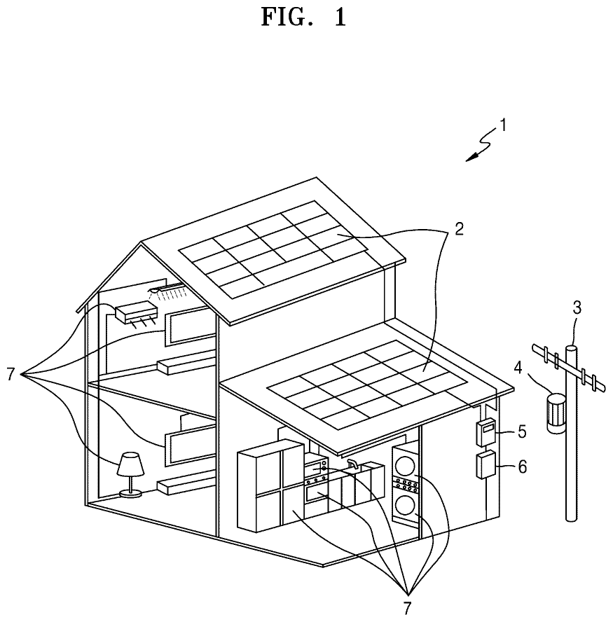

FIG. 1 is an exemplary diagram of a power supply structure of a building in which photovoltaic modules are installed according to an embodiment.

Referring to FIG. 1, a plurality of photovoltaic modules 2 may be installed on the roof of a building 1 and may generate energy using photovoltaic energy.

In case that a plurality of photovoltaic modules 2 are connected to each other, a photovoltaic module array may be configured. The photovoltaic module array is an assembly of a plurality of photovoltaic modules, which may include a single output terminal.

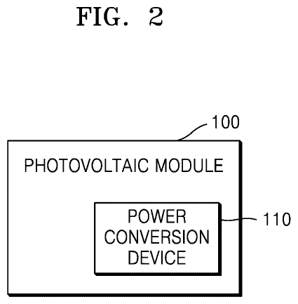

Meanwhile, a photovoltaic module 2 may include a power conversion device. For example, a power conversion device 110 of FIG. 2 may control power conversion of a photovoltaic module 2 and may optimize energy generation by including an optimizer. The power conversion device 110 of FIG. 2 may monitor a state of a photovoltaic module 2, determine whether there is a failure, and transmit data to the outside. For example, the power conversion device 110 of FIG. 2 may be a device including a converter (i.e. a device for converting alternating current into direct current) and an inverter (i.e. a device for converting direct current into alternating current).

In some embodiments, the power conversion device 110 of FIG. 2 may stop operation by executing a rapid shutdown (RSD) function depending on situations. In some embodiments, at least one of a photovoltaic module 2 or the power conversion device may include a communication module for power line communication.

A photovoltaic module 2 may include a monitoring system or a rapid shutdown system (RSD system).

An inverter 6 may convert power generated from photovoltaic modules 2 and supply the generated power into the building 1.

Meanwhile, commercial power supply transmitted through a power line 3 may be supplied to the building through a transformer 4.

A plurality of home appliances 7 may be operated by selectively receiving at least one of commercial power or power generated by photovoltaic modules 2. An electricity meter 5 may measure the amount of power consumed in the building 1.

In some embodiments, in case that a separate energy storage system (ESS) is provided in the building 1, power generated from photovoltaic modules 100 may be stored in the ESS.

FIG. 2 is an exemplary diagram of a photovoltaic module including a power conversion device according to an embodiment.

FIG. 2 illustrates a photovoltaic module 100 and a power conversion device 110. Although FIG. 2 illustrates that the power conversion device 110 is included within the photovoltaic module 100, this is not limited thereto. In other words, the power conversion device 110 may be a device independent of the photovoltaic module 100.

The photovoltaic module 100 may be a module which generates power using photovoltaic energy. For example, a plurality of photovoltaic modules 100 may be connected to each other to form a photovoltaic module array.

The power conversion device 110 may be connected to the photovoltaic module 100 to optimize an output voltage of the photovoltaic module 100. For example, the power conversion device 110 may optimize the output voltage so that the output of the photovoltaic module 100 is maximized.

For example, the power conversion device 110 may be module level power electronics (MLPE) configured in the unit of a module. Here, the MLPE may include a micro-inverter or DC optimizer (or power optimizer).

The micro-inverter may be a small photovoltaic inverter installed in the photovoltaic module 100. The micro-inverter is a device which converts power by being independently connected to each photovoltaic module 100, unlike a string inverter positioned centrally and connected to a plurality of photovoltaic modules. For example, in case that the power conversion device 110 is a micro-inverter, a single micro-inverter may be connected to a single photovoltaic module 100. In this case, the micro-inverter may convert power generated from the photovoltaic module 100, and the converted current may be output to a load or power grid.

The DC optimizer (or power optimizer) is a device which converts direct current power into alternating current power, like an inverter. The DC optimizer is a device which is independently connected to the photovoltaic module 100, combines and optimizes the power (direct current) generated from the photovoltaic module 100, and then transmits the power to a main inverter (e.g. a string inverter) to convert the power into alternating current. For example, in case that the power conversion device 110 is a DC optimizer, a single DC optimizer may be connected to a single photovoltaic module 100. In this case, the DC optimizer may optimize the power output from the photovoltaic module 100 and output the power to the main inverter. The current converted by the main inverter (e.g. from direct current to alternating current) may be output to a load or power grid.

The power conversion device 110 may be a MLPE connected to a photovoltaic module 100, but this is not limited thereto. For example, the power conversion device 110 may also be applied to a micro-inverter or DC optimizer. In some embodiments, the power conversion device 110 may be included in a converter or an inverter.

The power conversion device 110 may optimize the output voltage of each connected photovoltaic module 100 to output the voltage through maximum power point tracking control. The power conversion device 110 may identify a maximum power point voltage by performing the maximum power point tracking control which tracks the corresponding power and voltage when the photovoltaic module 100 generates maximum power. For example, a maximum power point tracking algorithm may be an algorithm which continuously adjusts the impedance of a photovoltaic module 100 or a photovoltaic module array so that a photovoltaic power generation system operates near the maximum power point when conditions such as irradiance, temperature, and load change.

For example, the power conversion device 110 may be connected in a one-to-one correspondence with the photovoltaic module 100, but this is not limited thereto. As another example, the power conversion device 110 may be installed in a many-to-one or many-to-many manner on the photovoltaic module 100 depending on a structure adopted by the photovoltaic power generation system. The installation forms of the power conversion device 110 and the photovoltaic module 100 are not limited to either one. In some embodiments, in case that a plurality of power conversion devices 110 are provided, the power conversion devices 110 may be connected in series to each other. In case that the power conversion devices 110 are DC optimizers, among a plurality of power conversion devices 110 connected in series to each other, the power conversion devices 110 positioned at the opposite ends may be connected to an inverter.

According to an embodiment of the disclosure, the inverter may be configured to be installed within a power conversion system (PCS) to perform power conversion to supply power generated from the photovoltaic module 100 to a load or grid. For example, the inverter may monitor various data received from the photovoltaic module 100, power conversion device 110, load, power system, or the like.

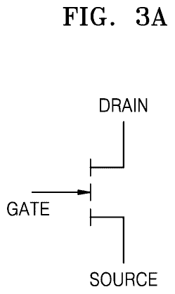

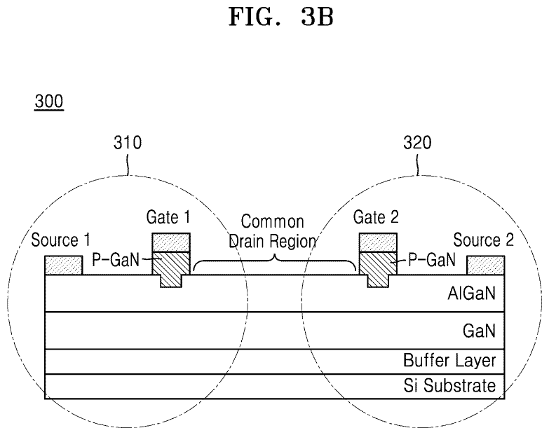

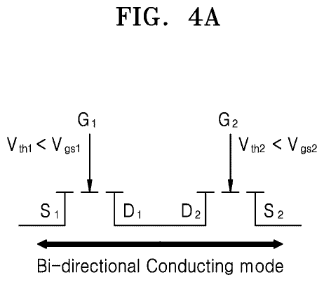

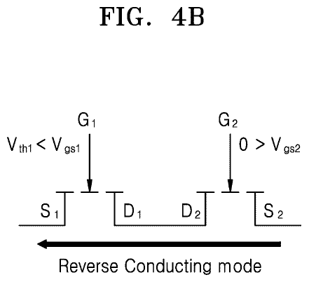

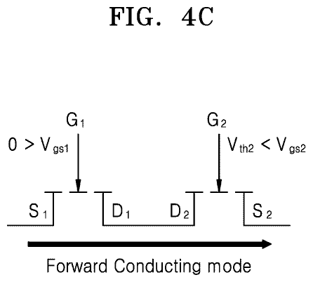

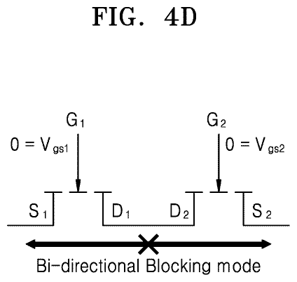

FIGS. 3A to 4D are structural diagrams of bidirectional multistage gallium nitride switches according to an embodiment.

FIG. 3A shows a circuit diagram of a gallium nitride (GaN) switch.

For example, in a gallium nitride switch, like other switching elements, the current flow from a drain DRAIN to a source SOURCE may be controlled by turning a gate GATE on or off.

Specifically, in case that the voltage applied to the gate is equal to or higher than a certain voltage (threshold voltage), the gate may be in an ON state in which current flows from the drain to the source, and in case that the voltage is lower than a threshold voltage, the gate may be in an OFF state in which no current flows from the drain to the source.

FIG. 3B is a schematic structural diagram of a bidirectional gallium nitride switch with a multistage structure including a gallium nitride switch of FIG. 3A.

For example, a bidirectional gallium nitride switch 600 may include a first gallium nitride switch 610 and a second gallium nitride switch 620.

The first gallium nitride switch 610 and the second gallium nitride switch 620 may be connected to each other within a single package to configure the bidirectional gallium nitride switch 600. In this regard, a drain terminal of the first gallium nitride switch 610 and a drain terminal of the second gallium nitride switch 620 may be connected to each other to form a structure which enables control of bidirectional current flow.

FIGS. 4A to 4D schematically illustrate current flows of the bidirectional gallium nitride switch 600 according to the state combinations of a gate G1 of the first gallium nitride switch 610 and a gate G2 of the second gallium nitride switch 620.

FIG. 4A shows a case where the gate G1 of the first gallium nitride switch 610 and the gate G2 of the second gallium nitride switch 620 are both in ON states, that is, a state where both gate voltages are higher than a threshold voltage (Vₜₕ₁<V_{gs1}, Vₜₕ₂<V_{gs2}). Because the first gallium nitride switch 610 and the second gallium nitride switch 620 are both in a conducting state, current may flow in both directions.

FIG. 4B may show a case where the gate G1 of the first gallium nitride switch 610 is in an ON state, that is, a state where the voltage of the gate G1 is higher than a threshold voltage (Vₜₕ₁<V_{gs1}), and a case where the gate G2 of the second gallium nitride switch 620 is in an OFF state, that is, a state where the voltage between the terminal of the gate G2 and the terminal of a source S2 is lower than a zero voltage (0>V_{gs2}). In this regard, the first gallium nitride switch 610 is in a conducting state, and the second gallium nitride switch 620 is in a state similar to that of a diode which conducts only in the direction of the first gallium nitride switch 610, so that current may flow only in the direction of the first gallium nitride switch 610 from the second gallium nitride switch 620. Here, the diode state of the second gallium nitride switch 620 may be to help understand the current flow, and because it is not a body diode like a silicon-based switching element, voltage drop may not occur due to the body diode.

FIG. 4C may show a case where the gate G1 of the first gallium nitride switch 610 is in an OFF state, that is, a state where the voltage between the terminal of the gate G1 and the terminal of a source S1 is lower than a zero voltage (0>V_{gs1}), and a case where the gate G2 of the second gallium nitride switch 620 is in an ON state, that is, a state where the voltage of the gate G2 is higher than a threshold voltage (Vₜₕ₂<V_{gs2}). The first gallium nitride switch 610 may enter a diode state in the direction of the second gallium nitride switch 32-, and the second gallium nitride switch 620 may be in a conducting state, so that current may only flow from the first gallium nitride switch 610 to the second gallium nitride switch 620.

FIG. 4D may show a case where the gate G1 of the first gallium nitride switch 610 and the gate G2 of the second gallium nitride switch 610 are both in OFF states (0=V_{gs1}, 0=V_{gs2}). In this regard, the channels of the first gallium nitride switch 610 and the second gallium nitride switch 620 are both closed, so that current may not flow in any direction.

As described above, a bidirectional gallium nitride switch 600 with a multistage structure according to the disclosure may reduce loss because a breakdown voltage due to a body diode does not occur. In some embodiments, because the distance between the source and drain of the first gallium nitride switch 610 and the distance between the drain and source of the second gallium nitride switch 620 are short, the switch may be suitable for high-speed switching. In some embodiments, because two gallium nitride switches 610 and 620 are included in a single package, the overall volume may be reduced.

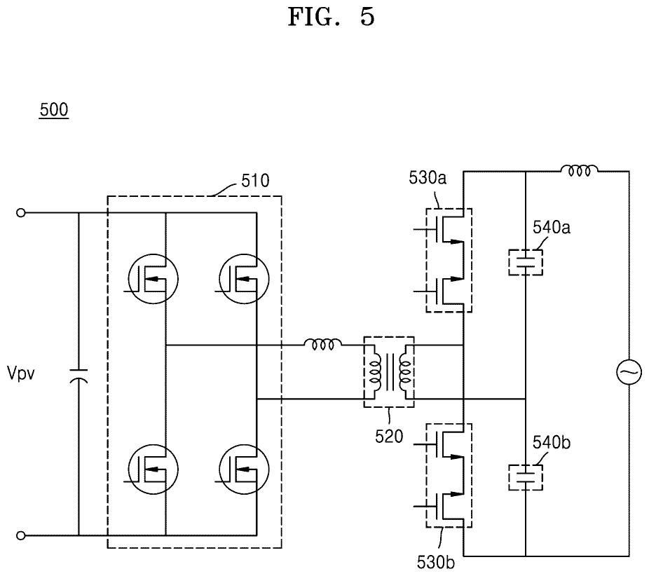

FIGS. 5 to 7 illustrate embodiments of a power conversion device including the bidirectional gallium nitride switch with a multistage structure described above.

FIG. 5 is a circuit diagram of an inverter including a cycloconverter structure according to an embodiment.

Referring to FIG. 5, an inverter 500 may include a primary-side full bridge circuit 510 connected to an input power supply, a transformer 520, bidirectional gallium nitride switches 530a and 530b of a secondary side, and capacitors 540a and 540b each connected to an output portion.

For example, the primary-side full bridge circuit 510 may be connected in parallel with an input power supply and an input capacitor and may include four switching elements. The four switching elements may be connected in parallel to each other in a state of series connection in pairs, and an end and another end of the transformer 520 may be connected to respective connection portions of the switching elements connected in series in pairs.

For example, input direct current may be converted into alternating current by controlling the ON/OFF states of the switching elements included in the primary-side full bridge circuit 510.

For example, the transformer 520 may electrically isolates the primary side and the secondary side to transmit the power on the primary side to the secondary side.

The primary-side full bridge circuit 510 may be connected to the primary side of the transformer 520, and the bidirectional gallium nitride switches 530a and 530b and the capacitors 540a and 540b may be connected to the secondary side of the transformer 520.

In some embodiments, the first bidirectional gallium nitride switch 530a and the second bidirectional gallium nitride switch 530b may be connected in series to each other, and an end of the secondary side of the transformer 520 may be connected therebetween.

In some embodiments, the first capacitor 540a and the second capacitor 540b may also be connected in series to each other, and another end of the secondary side of the transformer 520 may be connected therebetween.

Each of the bidirectional gallium nitride switches 530a and 530b, which are connected in series to each other, and the capacitors 540a and 540b, which are also connected in series to each other, may be connected in parallel to the output portion.

The inverter 200 including a cycloconverter structure according to the disclosure may include bidirectional gallium nitride switches. Accordingly, because the switch may be configured as a single package structure, the volume of the overall circuit may be reduced. In some embodiments, an effect of reducing the length of a line affected by noise in the overall circuit may be implemented. In some embodiments, the high-speed switching of a GaN element may minimize the volume of a passive element (a transformer, a capacitor, and an inductor) and increase efficiency.

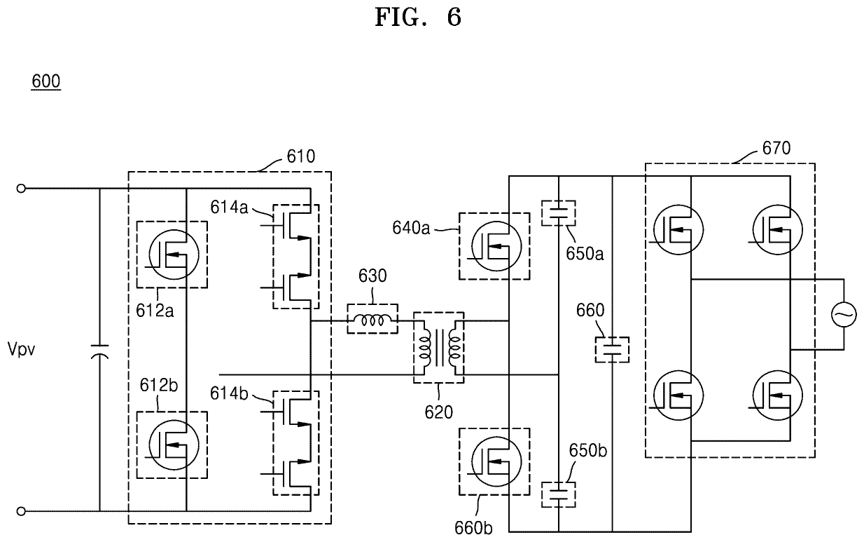

FIG. 6 is a circuit diagram of an inverter including a DAB structure according to an embodiment.

Referring to FIG. 6, an inverter 600 may include a DAB structure in which a primary-side full bridge circuit 610 and secondary-side full bridge circuit 370 each include a symmetrical structure.

For example, the primary-side full bridge circuit 610 may include four switching elements, and the switching elements may be configured as bidirectional gallium nitride switches.

For example, the primary-side full bridge circuit 610 may include two switching elements 612a and 612b connected in parallel to an input power supply and two bidirectional gallium nitride switches 614a and 614b connected in parallel to the input power supply. A third bidirectional gallium nitride switch 614a and a fourth bidirectional gallium nitride switch 614b, which are two bidirectional gallium nitride switches, may be connected in series to each other, and an end of the primary side of a transformer 620 may be connected therebetween.

The transformer 620 may electrically isolate the primary side and the secondary side thereof to transmit primary-side current to the secondary side. For example, an inductor 630 may be connected in series to the primary side of the transformer 620.

On the secondary side of the transformer 620, two switching elements 640a and 640b may be connected in series to each other, and an end of secondary-side output of the transformer 620 may be connected therebetween. In some embodiments, two capacitors 650a and 650b may be connected in series to each other on the secondary side of the transformer 620, and another end of secondary-side output of the transformer 620 may be connected therebetween.

For example, the two switching elements 640a and 640b and the two capacitors 650a and 650b may be connected in parallel to each other, and the elements and the capacitors may be connected in parallel to another capacitor 360 to be connected in parallel to the secondary-side full bridge circuit 370.

The inverter 600 including a DAB structure according to the disclosure may include bidirectional gallium nitride switches on the primary side thereof. Accordingly, by using the inverter 600, miniaturization of a passive element due to high efficiency, high voltage gain ratio, and high-speed switching may be achieved. In some embodiments, due to a single package structure, volume may be reduced and the influence of a noise line may be reduced.

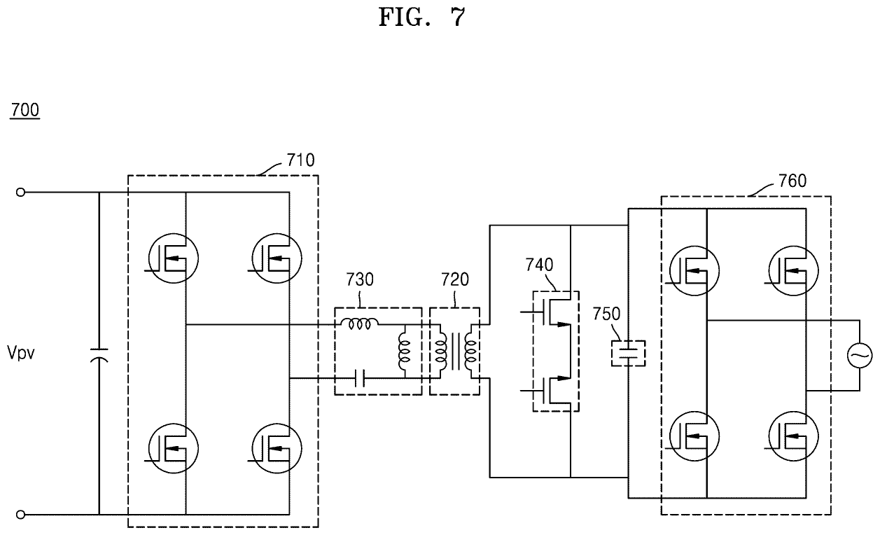

FIG. 7 is a circuit diagram of an LLC resonant inverter according to an embodiment.

Referring to FIG. 7, an inverter 700 may include a primary-side full bridge circuit 710, a transformer 720, an LLC circuit 730, a fifth bidirectional gallium nitride switch 740, a capacitor 750, and a secondary-side full bridge circuit 760.

For example, the primary-side full bridge circuit 710 may include four switching elements and may transmit current from an input power supply to the transformer 720 through the LLC circuit 730.

For example, the LLC circuit 730 may include two inductors connected in series to each other and one capacitor, and one of the two inductors may be connected in parallel to the primary side of the transformer 720.

The transformer 720 may transmit primary-side current to the secondary side thereof, and the primary side and the secondary side may be electrically isolated from each other.

A fifth bidirectional gallium nitride switch 740 may be connected in parallel to the secondary side of the transformer 720. In some embodiments, the capacitor 750 may also be connected in parallel to the gallium nitride switch 740.

In some embodiments, the capacitor 750 and the secondary-side full bridge circuit 760 may be also connected in parallel to each other so that the final converted current may be output.

The LLC resonant inverter 700 according to the disclosure may include bidirectional gallium nitride switches on the secondary side thereof. Accordingly, by using the inverter 700, miniaturization of a passive element due to high efficiency, high voltage gain ratio, and high-speed switching may be achieved. In s ome embodiments, due to a single package structure, volume may be reduced and the influence of a noise line may be reduced.

According to a bidirectional gallium nitride switch and a power conversion device including the bidirectional gallium nitride switch according to the disclosure, loss due to voltage drop occurring in the body diode of a conventional silicon-based switching element may be reduced. In some embodiments, two gallium nitride switches may be included in a single package, which may reduce volume and cost and may optimize noise lines.

Although the detailed description of the disclosure has described specific embodiments, it is of course possible to make various modifications without departing from the scope of the disclosure. Accordingly, the scope of the disclosure should not be limited to the described embodiments but should be defined by the claims described below and the equivalents of the claims.

1. A bidirectional gallium nitride switch, comprising: a first gallium nitride (GaN) switch and a second gallium nitride switch, each of which includes a gate terminal, a drain terminal, and a source terminal, wherein
a drain terminal of the first gallium nitride switch and a drain terminal of the second gallium nitride switch are connected to each other, so that bidirectional current flow is controllable by ON/OFF control of each of a gate terminal of the first gallium nitride switch and a gate terminal of the second gallium nitride switch.

2. The bidirectional gallium nitride switch of claim 1, wherein
the first gallium nitride switch and the second gallium nitride switch are included within a same package.

3. A power conversion device, comprising the bidirectional gallium nitride switch according to claim 1.

4. The power conversion device of claim 3, wherein
the power conversion device comprises:
a primary-side full bridge circuit connected to an input power supply;
a transformer configured to transmit an output of the full bridge circuit to a secondary side; and
a converter portion configured to transmit secondary-side output of the transformer to an output portion of the power conversion device.

5. The power conversion device of claim 4, wherein
the power conversion device comprises an isolated inverter which converts primary-side direct current power into secondary-side alternating current power.

6. The power conversion device of claim 4, wherein
the converter portion comprises a first bidirectional gallium nitride switch, a second bidirectional gallium nitride switch, a first capacitor, and a second capacitor.

7. The power conversion device of claim 6, wherein
in the converter portion,
an end of secondary-side output of the transformer is connected between the first bidirectional gallium nitride switch and the second bidirectional gallium nitride switch, which are connected in series to each other, and
another end of secondary-side output of the transformer is connected between the first capacitor and the second capacitor, which are connected in series to each other, and
the first bidirectional gallium nitride switch and the second bidirectional gallium nitride switch and the first capacitor and the second capacitor are connected in parallel to an output portion of the power conversion device.

8. The power conversion device of claim 3, comprising
the power conversion device has a dual active bridge (DAB) structure in which a transformer and an inductor connected in series to the transformer are connected between a primary-side full bridge circuit and secondary-side full bridge circuit, wherein
the primary-side full bridge circuit includes a third bidirectional gallium nitride switch and a fourth bidirectional gallium nitride switch.

9. The power conversion device of claim 8, wherein
the primary-side full bridge circuit includes a first switching element and a second switching element, connected in series to each other, and a third bidirectional gallium nitride switch and a fourth bidirectional gallium nitride switch, connected in series to each other, are connected in parallel to an input power supply.

10. The power conversion device of claim 3, wherein:
the power conversion device includes a primary-side full bridge circuit;
a first inductor, a second inductor and a third capacitor connected to the primary-side full bridge circuit and connected in series to each other;
a transformer including a primary side connected in parallel to the first inductor or the second inductor;
a fifth bidirectional gallium nitride switch connected in parallel to a secondary side of the transformer;
a fourth capacitor connected in parallel to a fifth bidirectional gallium nitride switch; and
a secondary-side full bridge circuit connected in parallel to the fourth capacitor.
